(19) United States
(12) Patent Application Publication
(10) Pub. No.: US 2009/0039444 A1
(43) Pub. Date: Feb. 12, 2009

(54) SEMICONDUCTOR DEVICE AND METHOD OF FABRICATING THE SAME

(75) Inventor: Atsuhiro SUZUKI, Yokkaichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/180,828

(22) Filed: Jul. 28, 2008

(30) Foreign Application Priority Data
Aug. 8, 2007 (JP) 2007-206766

(51) Int. Cl. H01L 21/8234; H01L 27/088

(52) U.S. Cl. 257/392; 438/275; 257/E27.06; 257/E21.616

(57) ABSTRACT

A semiconductor device includes a semiconductor substrate including an upper surface having a first region including a pair of first impurity diffusion regions and a first channel region located between the impurity diffusion regions and a second region including a recess having a predetermined depth relative to the upper surface, a first gate insulating film, a first gate electrode of a first transistor supplying a first voltage, a second gate insulating film having a second thickness larger than a first thickness of the first gate insulating film, an upper surface of the second gate insulating film located at a same level as an upper surface of the first gate insulating film, and a second gate electrode of a second transistor supplying a second voltage being higher than the first voltage.

### CROSS-REFERENCE TO RELATED APPLICATIONS

This application is based on and claims the benefit of priority from the prior Japanese Patent Application No. 2007-206766, filed on Aug. 8, 2007, the entire contents of which are incorporated herein by reference.

### BACKGROUND OF THE INVENTION

1. Field of the Invention

The present invention relates to a semiconductor device provided with a plurality of transistors including gate insulating films with different films thicknesses respectively, and a method of fabricating the same.

2. Description of the Related Art

Some types of semiconductor devices are provided with both high- and low-breakdown voltage transistors. These transistors include gate insulating films with film thicknesses differing from each other according to values of breakdown voltages respectively. As a result, a plurality of processes are necessitated in order to form individual gate insulating films. For example, JP-A-2004-134568 discloses a semiconductor device in which gate insulating films have different film thicknesses. However, differences in level or steps result from the differences in the film thicknesses of the gate insulating films when a whole chip is considered. Occurrence of the steps poses problems in a chemical mechanical polishing (CMP) process, an etching process and the like in the fabrication process. Accordingly, the number of processes is increased so that the steps can be coped with, whereupon the process capability is reduced.

A silicon substrate has an upper surface including an area in which a high-breakdown voltage transistor is to be formed. A recess or depression has conventionally been formed previously by an etching process in the aforesaid area of the upper surface or an area in which a gate insulating film with a larger film thickness is to be formed, as shown by JP-A-2001-203285. Consequently, a gate insulating film with a larger film thickness is formed in the area of higher breakdown voltage transistor, whereas another gate insulating film with a smaller film thickness is formed in an area of lower breakdown voltage transistor. As a result, steps can be prevented from being formed in the upper surface of the silicon substrate while a thinner gate insulating film is formed on the area of the lower breakdown voltage transistor, and accordingly, the defects in the processing due to the steps can be overcome in the subsequent process.

However, even when the upper surfaces of the higher and lower breakdown voltage transistors are on the same level while the gate insulating films are formed as described above, not all the defects can be overcome. For example, a contact hole is formed in the gate insulating film formed on the upper surface of a source/drain region so that the surface of the silicon substrate is exposed. Etching conditions differ between higher and lower breakdown voltage transistor regions in the aforesaid exposing process. Accordingly, an amount of etching is insufficient for a thicker gate insulating film when the etching conditions are caused to adapt to etching of a thinner gate insulating film. On the contrary, when the etching conditions are caused to adapt to etching of a thicker gate insulating film, a thinner gate insulating film is excessively etched such that the silicon substrate would be damaged.

### BRIEF SUMMARY OF THE INVENTION

According to a first aspect of the present invention, there is provided a semiconductor device comprising a semiconductor substrate including an upper surface having a first region and a second region isolated to the first region with an element isolation insulating region, the first region including a pair of first impurity diffusion regions and a first channel region located between the impurity diffusion regions, the second region including a recess having a predetermined depth relative to the upper surface, a pair of second impurity diffusion regions formed from an inner surface of the recess to the upper surface of the semiconductor substrate, and a second channel region located in a bottom portion of the recess between the impurity diffusion regions; a first gate insulating film formed on the first channel region, the first gate insulating film including a first thickness; a first gate electrode of a first transistor supplying a first voltage formed on the first gate insulating film; a second gate insulating film formed on the second channel region located at the bottom portion of the recess, the second gate insulating film including a second thickness being larger than the first thickness of the first gate insulating film, and an upper surface of the second gate insulating film located to a same level as an upper surface of the first gate insulating film; a second gate electrode of a second transistor supplying a second voltage being higher than the first voltage, formed on the second gate insulating film; at least one first plug contacting to one of the first impurity diffusion regions; and at least one second plugs contacting to one of the second impurity diffusion regions on the upper surface of the semiconductor substrate except the recess.

According to a second aspect of the present invention, there is provided a method of fabricating a semiconductor device which includes a lower breakdown voltage transistor formed on a semiconductor substrate and having a first gate electrode formed on a first gate insulating film having a first film thickness, and a higher breakdown voltage transistor formed on the semiconductor substrate and having a second gate electrode formed on a second gate insulating film, the higher breakdown voltage transistor having a higher breakdown voltage than the lower breakdown voltage transistor, the method comprising forming a recess with a depth corresponding to a difference between the first and second film thicknesses of the first and second gate insulating films; forming the second gate insulating film with the second film thickness on an upper surface of the recess; forming the first gate insulating film with the first film thickness on an upper surface of the semiconductor substrate; forming first and second gate electrodes on upper surfaces of the first and second gate insulating films respectively; and forming a source/drain region on the semiconductor substrate by introducing an impurity e electrodes serving as masks.

### BRIEF DESCRIPTION OF THE DRAWINGS

Other objects, features and advantages of the present invention will become clear upon reviewing the following description of one embodiment with reference to the accompanying drawings, in which:

FIG. 1 is a schematic sectional view of a semiconductor device of one embodiment in accordance with the present invention; and

FIGS. 2 to 13 are schematic sectional views of the semiconductor device in sequential steps of the fabricating process (Nos. 1 to 12).

### DETAILED DESCRIPTION OF THE INVENTION

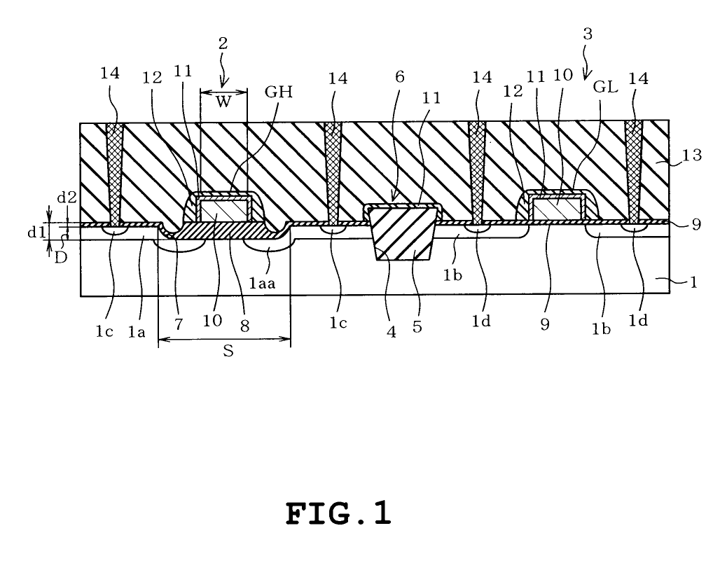

One embodiment of the present invention will be described with reference to the accompanying drawings. FIG. 1 is a schematic sectional view of a higher breakdown voltage transistor 2 and a lower breakdown voltage transistor 3 formed on a semiconductor substrate or a silicon substrate 1. The higher breakdown voltage transistor 2 is a transistor used for controlling a write voltage (about 20V-30V) in NAND nonvolatile memories, for example. The lower breakdown voltage transistor 3 is a transistor used for controlling a power supply voltage (about 1 V-5 V) in the NAND nonvolatile memories.

A trench 4 is formed in a boundary between forming regions of the higher and lower breakdown voltage transistors 2 and 3. An insulating film 5 such as a silicon oxide film is buried in the trench 4, whereupon an element isolation region 6 is defined. Furthermore, a recess 7 is formed in the silicon substrate 1 so as to correspond to a gate electrode GH in the forming region of the higher breakdown voltage transistor 2. The recess 7 has a depth D and a width S that is larger than a width W of the gate electrode GH. The recess 7 has opposite ends each of which has an arc-shaped section such that each end gradually becomes shallower outward from a central side thereof. A silicon oxide film 8 is formed on an upper surface of the recess 7 and serves as a higher breakdown voltage gate insulating film. The silicon oxide film 8 has a predetermined film thickness d1 and is formed so as to become gradually thinner outward from the central side of the recess 7 at each end of the recess. Furthermore, the silicon oxide film 8 includes a tapered portion in the end portion.

A silicon oxide film 9 serving as a lower breakdown voltage gate insulating film is formed on an upper surface part of the silicon substrate 1 corresponding to a gate electrode GL of the forming region of the lower breakdown voltage transistor 3. The silicon oxide film 9 has a film thickness d2. The silicon oxide film 9 is also formed on another part of the upper surface of the silicon substrate 1. The film thickness d1 of the silicon oxide film 8 is set so as to correspond to the breakdown voltage of the higher breakdown voltage transistor 2. The film thickness d2 of the silicon oxide film 9 is set so as to be smaller than that of the silicon oxide film 8 (d2<d1) and so as to correspond to the breakdown voltage of the lower breakdown voltage transistor 3. The depth D of the recess 7 is set so as to be equal to the difference between the film thicknesses d1 and d2 of the silicon oxide films 8 and 9 (Δd=D). As the result of formation of the film 8 on the recess 7, the aforesaid difference Δd is substantially compensated such that upper surfaces of the silicon oxide films 8 and 9 are on the same level.

Impurity diffusion regions 1a and 1b are formed in a surface layer of the silicon substrate 1. The impurity diffusion regions la are located at both sides of the gate electrode GH respectively, whereas the impurity diffusion regions 1b are located at both sides of the gate electrode GL respectively. The impurity diffusion regions 1a and 1b serve as respective source/drain regions. Each impurity diffusion region 1a corresponding to the higher breakdown voltage transistor 2 includes a region 1aa that is formed so as to become gradually deeper toward the central part of the recess 7 at the corresponding end of the recess. Furthermore, each impurity diffusion region 1a includes a high-concentration impurity region 1c corresponding to a contact region. Each impurity diffusion region 1b includes a high-concentration impurity region 1d corresponding to a contact region. The silicon oxide film 9 is formed over the impurity diffusion regions 1a and 1b as described above.

The gate electrodes GH and GL are formed on the silicon oxide films 8 and 9 respectively. A polycrystalline silicon film 10 is employed as an electrode material for each gate electrode GH or GL. A silicon oxide film 11 is formed co as to cover sidewalls and an upper surface of each polycrystalline silicon film 10. A spacer 12 is formed which comprises a silicon oxide film for formation of a lightly doped drain (LDD) structure which is necessitated in forming another transistor not shown. Since the silicon oxide films 8 and 9 are formed so as to be on the same level as described above, the gate electrodes GH and GL are also formed so as to be on the same level. A silicon oxide film 13 serving as an interlayer insulating film is formed so as to cover overall upper surfaces of the silicon substrate 1 and gate electrodes GH and GL. Contact holes are formed in the silicon oxide film 13. Contact plugs 14 are buried in the respective contact holes. Contact plugs 14 electrically connect impurity diffusion regions 1a, 1b with upper wiring layers (not shown).

Since the above-described structure is employed in the embodiment, the higher and lower breakdown voltage transistors 2 and 3 are formed with the silicon oxide films 8 and 9 serving as the gate insulating films with the film thicknesses according to the breakdown voltages, respectively. The recess 7 is formed in the silicon substrate 1 such that the upper surfaces of the silicon oxide films 8 and 9 are on the same level. Consequently, the above-described structure can prevent the processing difficulty due to difference in level between the silicon oxide films 8 and 9 serving as the gate insulating films in the processing of the gate electrodes GH and GL. Furthermore, the recess 7 corresponding to the higher breakdown voltage transistor 2 has a larger width S than the gate electrode GH and is formed so as to become gradually shallower at the opposite ends. Accordingly, the source/drain region is formed so as to be partially deeper in compliance with the configuration of the recess 7. Consequently, electric field concentration on an end of the source/drain region can be alleviated, whereupon the breakdown voltage of the transistor can be improved.

And the contact holes corresponding to the higher breakdown voltage transistor 2 are formed in the outside of the recess 7. Since a height of the contact holes corresponding to the higher breakdown voltage transistor 2 is same as a height of the contact holes corresponding to the lower breakdown voltage transistor 3, the contact holes corresponding to the higher breakdown voltage transistor 2 can be formed together with the contact holes corresponding to the lower breakdown voltage transistor 3 without the damage to the silicon substrate 1.

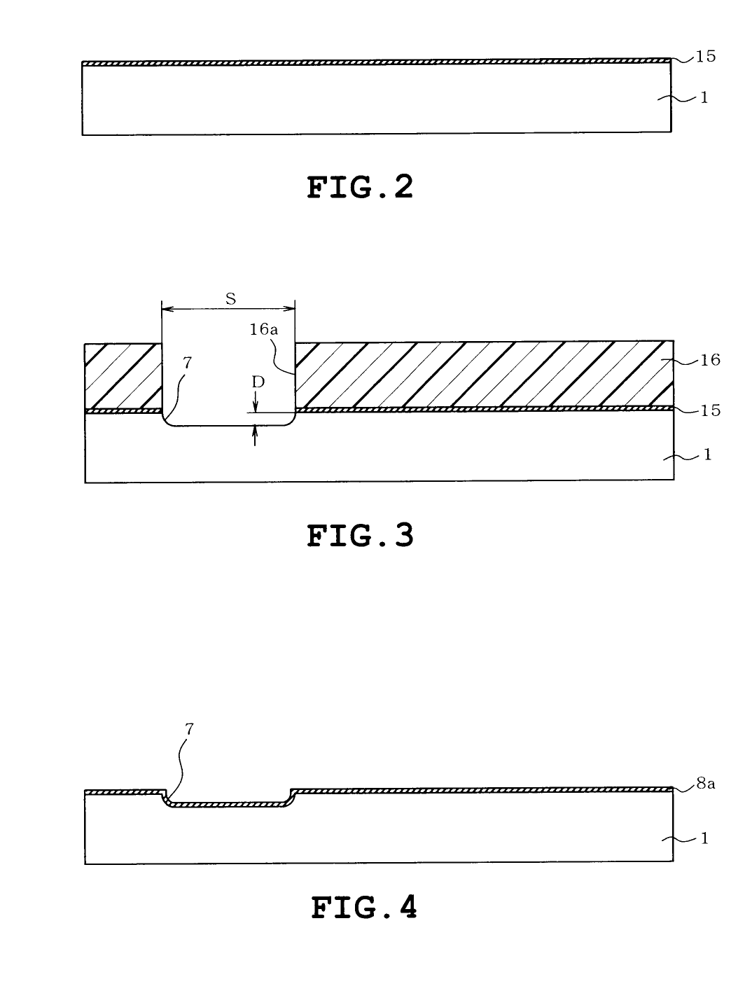

The fabrication process of the foregoing structure will now be described with reference to FIGS. 2 to 13. Firstly, a silicon oxide film 15 serving as a sacrificial oxide film is formed on the upper surface of the silicon substrate 1 as shown in FIG. 2. Subsequently, as shown in FIG. 3, a photoresist 16 is coated on the oxide film 15 by a photolithography process so that an opening 16a is formed in a recess region is patterned and formed. Thereafter, the silicon oxide film 15 is removed by etching, and the silicon substrate 1 is etched by an isotropic dry etching process so that the recess 7 is formed. In this case, the recess 7 is formed so that each of the opposite ends thereof has the arc-shaped section and so that each end becomes gradually shallower outward from the central side. Subsequently, as shown in FIG. 4, the photoresist 16 is removed and the silicon oxide film 15 is once removed. Thereafter, a silicon oxide film 8a is formed so as to cover both the inner surface of the recess 7 and the upper surface of the silicon substrate 1.

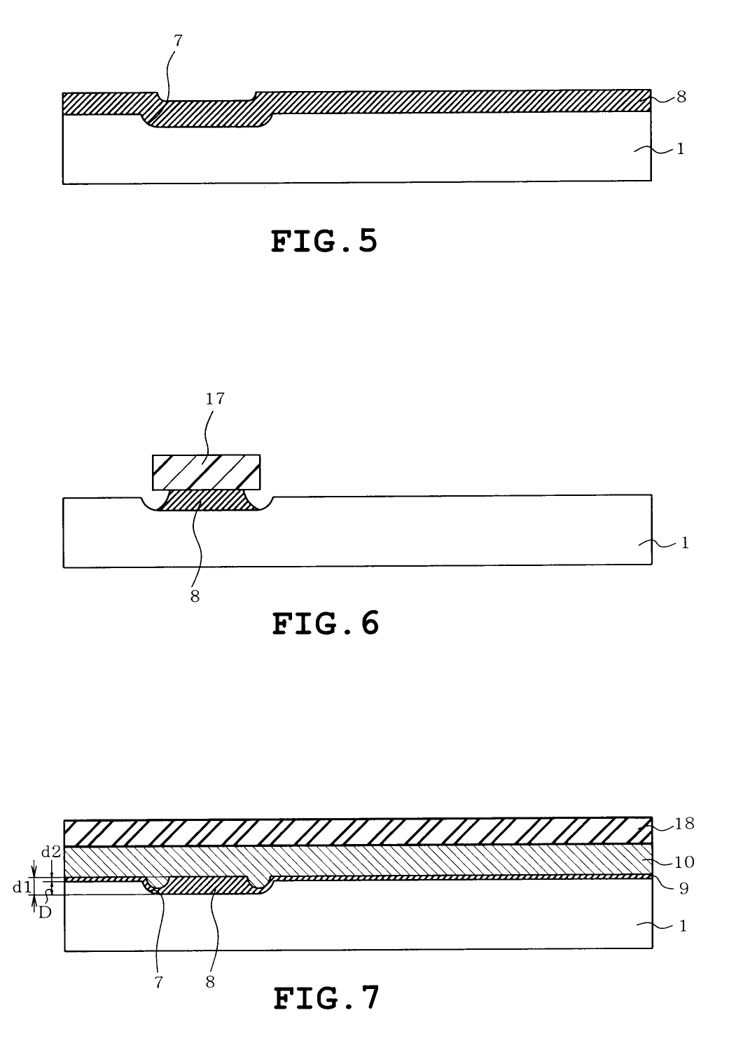

Subsequently, as shown in FIG. 5, the silicon oxide film 8a is formed thick over the overall upper surface of the silicon substrate 1 into the silicon oxide film 8. The silicon oxide film 8 serves as the gate insulating film after processing and is set at the film thickness d1 corresponding to the breakdown voltage of the higher breakdown voltage transistor 2. Subsequently, as shown in FIG. 6, the photoresist 17 is patterned by the photolithography process so that only the part of the silicon oxide film 8 on the recess 7 is left. In this case, a wet etching process is carried out using a chemical such as diluted hydrofluoric acid (DHF) so that an extra part of the silicon oxide film 8 is removed. As a result, a part of the silicon oxide film 8 remains on the recess 7. Since the wet etching process is employed, the silicon oxide film 8 is etched to the inside thereof located lower than the pattern end of the photoresist 17. The sectional shape is rendered curved. The photoresist 17 is removed after the processing.

Subsequently, as shown in FIG. 7, the silicon oxide film 9 which serves as the gate insulating film for the lower breakdown voltage transistor 3 is formed in the region other than the silicon oxide film 8 so as to have the film thickness d2. In this case, the film thickness d2 of the silicon oxide film is set so as to be equal to the difference between the film thickness d1 of the silicon oxide film 8 and the depth D of the film thickness (d1-D), whereupon the upper surfaces of the silicon oxide films 8 and 9 are on the same level. Thereafter, the polycrystalline silicon film 10 is formed on the upper surface of the silicon oxide film 9. The polycrystalline film serves as the electrode material of the gate electrodes GH and GL, and a silicon nitride film 18 which is a processing hard mask material.

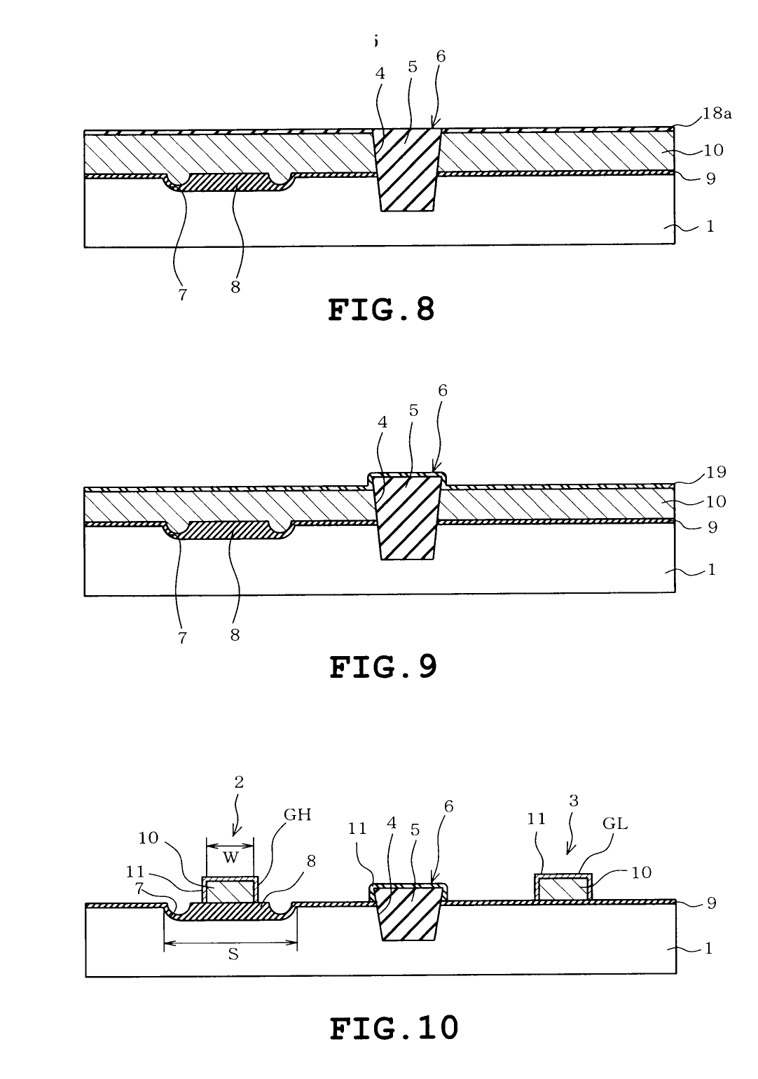

Subsequently, as shown in FIG. 8, the element isolation region 6 is formed. Firstly, photoresist is patterned for trench formation by the photolithography process. Dry etching is then carried out by the reactive ion etching method. In this case, the silicon nitride film 18 is etched with the photoresist serving as a mask, and the polycrystalline silicon film 10, silicon oxide film 9 and silicon substrate 1 are etched with the processed silicon nitride film 18 serving as a hard mask so that a predetermined depth is reached, thereby forming the trench 4. Subsequently, the silicon oxide film 5 is deposited in the trench 4 so as to be buried in the same. Thereafter, a planarizing process is carried out with the silicon nitride film 18 serving as a stopper by the chemical mechanical polishing (CMP) method, whereby the trench 4 is filled with the silicon oxide film 5. As a result, an element isolation region employing a shallow trench isolation (STI) method is formed. In this case, since the film thickness of the silicon nitride film 18 is reduced by the etching process or the CMP process, the silicon nitride film 18 is rendered thinner into the silicon nitride film 18a.

Subsequently, as shown in FIG. 9, the silicon nitride film 18a is removed and a silicon oxide film 19 having a small film thickness is formed over a whole polycrystalline silicon film 10 and the upper surface of the silicon oxide film 5. Subsequently, as shown in FIG. 10, photoresist is patterned by the photolithography process, and the polycrystalline silicon film 10 is etched so that the gate electrodes GH and GL are formed. A silicon oxide film 11 is formed on sidewalls and upper surface of the processed polycrystalline silicon film 10.

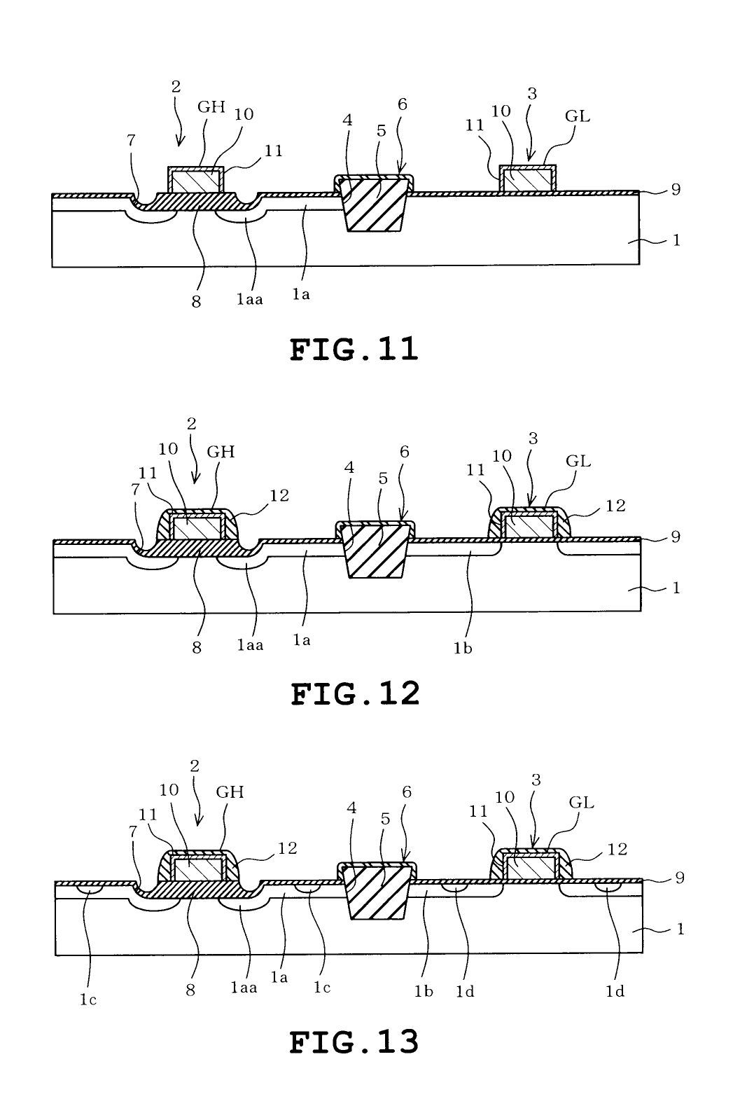

Subsequently, as shown in FIG. 11, the impurity diffusion region 1a is formed which serves as a source/drain region of the higher breakdown voltage transistor 2. More specifically, a region of the higher breakdown transistor 2 is exposed by the photolithography process, and the photoresist is patterned so as to cover another region of the transistor 2. Ion implantation of impurities is carried out with the processed photoresist serving as a mask. In this case, although the impurity diffusion region 1a is formed so as to reach the predetermined depth as described above, the upper surface of the semiconductor substrate 1 is rendered lower in the region of recess 7. Consequently, the impurity diffusion region 1a is formed deeper by an amount corresponding to the lowering of the upper surface of the silicon substrate 1 thereby to be formed into an impurity diffusion region 1aa which protrudes downward into the shape of an arc so as to conform to the configuration of the end of the reset 7.

Subsequently, as shown in FIG. 12, the impurity diffusion region 1b is formed as the source/drain region of the lower breakdown voltage transistor 3. The impurity diffusion region 1b is formed by carrying out the photolithography process in the same manner as described above so that the region of the lower breakdown voltage transistor 3 is exposed. Ion implantation of impurities is carried out in the exposed region so that the impurity diffusion region 1b is formed in the region. Since the impurity diffusion region 1b has a different impurity concentration from that of the impurity diffusion region 1a of the higher breakdown voltage transistor 2, ion implantation is separately carried out so that the impurity diffusion regions 1a and 1b are formed. Subsequently, a silicon oxide film for formation of a spacer 12 is deposited on the whole upper surface. Thus, spacers 12 are formed by a spacer formation process for the gate electrodes GH and GL respectively. Thereafter, an ion implantation process is carried out for forming the LDD structure by utilizing the spacers 12, whereupon high-concentration impurity regions (not shown) are formed.

Subsequently, as shown in FIG. 13, high-concentration impurity diffusion regions 1c and id are formed in the source/drain regions 1a and 1b for provision of ohmic contact. Subsequently, a silicon oxide film 13 is formed as an interlayer insulating film. Contact holes are formed in the silicon oxide films 13 and 9 subsequently to a planarizing process such as CMP process, whereby the upper surface of the high-concentration impurity diffusion region 1c is exposed. In this case, in the embodiment, only the silicon oxide film 9 is formed as a gate insulating film for lower breakdown voltage on the upper surface of the silicon substrate 1 in each of the contact hole forming portions of the higher and lower breakdown voltage transistors 2 and 3. Accordingly, contact holes can be formed together with the silicon oxide film. Thereafter, a conductor is buried in each contact hole and a planarizing process is carried out so that the contact plugs 14 are formed. Subsequently, a wiring process is carried out and then the semiconductor device is completed although the connecting arrangement for the contact plugs 14 is not shown in FIG. 1.

According to the foregoing embodiment employing the above-described fabricating process, the recess 7 is formed in the region where the gate electrode GH of the higher breakdown voltage transistor 2 is formed, and the upper surface of the silicon oxide film 8 used as the thicker gate insulating film is set so as to be on the same level as the upper surface of the silicon oxide film 9. Furthermore, the silicon oxide film 9 is formed on the upper surface of the source/drain regions 1a and 1b. Accordingly, the fabricating process excludes the step of removing the thicker silicon oxide film 8. Furthermore, the contact holes can be formed together with the lower breakdown voltage transistor 3. As a result, the fabrication process can be simplified and the workability can be improved.

Furthermore, since the recess 7 is formed by the isotropic dry etching process, no step is formed on each end such that the recess 7 can be configured so that the depth thereof is continuously changed, whereupon each end of the impurity diffusion region 1a can be shaped so as to be formed deeper in a convex state. Consequently, the breakdown voltage can be improved since an offset diffusion layer is substantially increased in length.

The invention should not be limited to the foregoing embodiment. The embodiment may be modified or expanded as follows. The recess 7 may have a sectional shape linearly inclined so that each end becomes gradually shallower. The width S of the recess 7 may be set according to the breakdown voltage of the higher breakdown voltage transistor 2.

The invention may be applied to a nonvolatile semiconductor memory such as a NAND or NOR flash memory. In this case, an intergate insulating film may partially be opened in the configuration that the memory has a floating gate and a control gate with the gate electrodes GH and GL corresponding to the arrangement of a memory cell transistor, whereby the gate insulating film is short-circuited.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate including an upper surface having a first region and a second region isolated from the first region with an element isolation insulating region, the first region including a pair of first impurity diffusion regions and a first channel region located between the impurity diffusion regions, the second region including a recess having a predetermined depth relative to the upper surface, a pair of second impurity diffusion regions formed from an inner surface of the recess to the upper surface of the semiconductor substrate, and a second channel region located in a bottom portion of the recess between the impurity diffusion regions;
a first gate insulating film formed on the first channel region and having a first thickness;
a first gate electrode of a first transistor supplying a first voltage formed on the first gate insulating film;
a second gate insulating film formed on the second channel region located at the bottom portion of the recess, the second gate insulating film having a second thickness larger than the first thickness of the first gate insulating film, and an upper surface of the second gate insulating film located at a same level as an upper surface of the first gate insulating film;
a second gate electrode of a second transistor supplying a second voltage being higher than the first voltage, formed on the second gate insulating film;
at least one first plug contacting to one of the first impurity diffusion regions; and
at least one second plug contacting to one of the second impurity diffusion regions on the upper surface of the semiconductor substrate except the recess.

2. The device according to claim 1, wherein the recess has a larger width than the second gate electrode.

3. The device according to claim 1, wherein the second gate insulating film includes a middle portion having the second thickness and an end portion having a third thickness being thinner than the second thickness.

4. The device according to claim 3, wherein the second gate insulating film includes a tapered portion in the end portion.

5. The device according to claim 1, wherein an upper surface of the first gate electrode is located at a same level as an upper surface of the second gate electrode.

6. The device according to claim 1, wherein an upper portion of the first plug is located at a same level as an upper surface of the second plug.

7. The device according to claim 1, wherein a thickness of the first gate electrode is same as a thickness of the second gate electrode.

8. A method of fabricating a semiconductor device which includes a lower breakdown voltage transistor formed on a semiconductor substrate and having a first gate electrode formed on a first gate insulating film having a first film thickness, and a higher breakdown voltage transistor formed on the semiconductor substrate and having a second gate electrode formed on a second gate insulating film, the higher breakdown voltage transistor having a higher breakdown voltage than the lower breakdown voltage transistor, the method comprising:
forming a recess with a depth corresponding to a difference between the first and second film thicknesses of the first and second gate insulating films;
forming the second gate insulating film with the second film thickness on an upper surface of the recess;
forming the first gate insulating film with the first film thickness on an upper surface of the semiconductor substrate;
forming first and second gate electrodes on upper surfaces of the first and second gate insulating films respectively; and
forming a source/drain region on the semiconductor substrate by introducing an impurity e electrodes serving as masks.

9. The method according to claim 8, wherein the recess is formed by etching the semiconductor substrate by a wet etching process.

10. The method according to claim 8, wherein the gage electrode forming step includes:
forming conductor films on upper surfaces of the first and second gate insulating films, the conductor films serving as the first and second gate electrodes respectively, the conductor films having respective upper faces;
coating a hard mask material on the upper surfaces of the conductor films; and
etching the conductor films with the hard mask material serving as a mask and forming a trench in the semiconductor substrate and burying an insulating film in the trench, thereby forming element isolation regions of the higher and lower breakdown voltage transistors respectively.

11. The method according to claim 9, wherein the gage electrode forming step includes:
forming conductor films on upper surfaces of the first and second gate insulating films, the conductor films serving as the first and second gate electrodes respectively, the conductor films having respective upper faces;
coating a hard mask material on the upper surfaces of the conductor films; and
etching the conductor films with the hard mask material serving as a mask and forming a trench in the semiconductor substrate and burying an insulating film in the trench, thereby forming element isolation regions of the higher and lower breakdown voltage transistors respectively.
